(19) United States
(12) Patent Application Publication
(10) Pub. No.: US 2026/0143783 A1
(43) Pub. Date: May 21, 2026

(54) SEMICONDUCTOR PACKAGE WITH HOMOGENOUS BONDING

(71) Applicant: SAMSUNG ELECTRONICS CO., LTD., Suwon-si (KR)

(72) Inventors: Wonil LEE, Suwon-si (KR); Raeyoung KANG, Suwon-si (KR); Hyeongjin HWANG, Suwon-si (KR); Yiyoung KIM, Suwon-si (KR)

(73) Assignee: SAMSUNG ELECTRONICS CO., LTD., Suwon-si (KR)

(21) Appl. No.: 19/386,782

(22) Filed: Nov. 12, 2025

(30) Foreign Application Priority Data
Nov. 21, 2024 (KR) 10-2024-0167759

(51) Int. Cl. H01L 23/00; H01L 25/18; H10B 80/00; H10D 80/30

(52) U.S. Cl. CPC H10D 80/30; H10B 80/00; H10W 90/00; H10W 72/921; H10W 72/926; H10W 72/932; H10W 72/936; H10W 72/944; H10W 72/9445; H10W 80/743; H10W 90/297; H10W 90/792

(57) ABSTRACT

A semiconductor package includes a first semiconductor chip comprising a first semiconductor substrate and a first via electrode passing through at least a portion of the first semiconductor substrate; a second semiconductor chip on the first semiconductor chip and comprising a second semiconductor substrate; a first bonding pad structure between the first semiconductor chip and the second semiconductor chip; a first dummy bonding pad structure between the first semiconductor chip and the second semiconductor chip; and a first inter-chip insulation layer on a surface of the first semiconductor chip, and a second inter-chip insulation layer on a surface of the second semiconductor chip, in which the first bonding pad structure comprises: a first bonding pad on the surface of the first semiconductor chip, and a second bonding pad on the surface of the second semiconductor chip.

### CROSS-REFERENCE TO RELATED APPLICATION

This application is based on and claims priority under 35 U.S.C. § 119 to Korean Patent Application No. 10-2024-0167759, filed on Nov. 21, 2024, in the Korean Intellectual Property Office, the disclosure of which is incorporated herein in its entirety by reference.

### BACKGROUND

The present disclosure relates to a semiconductor package, and more particularly, to a semiconductor package including directly bonded semiconductor chips.

In accordance with the development of the electronics industry and user demand, electronic devices are becoming smaller and lighter, and semiconductor packages used in electronic devices are demanded to be smaller and lighter, as well as have higher performance and larger capacities. To implement high performance and large capacity along with miniaturization and weight reduction, research and development are continuously being conducted on semiconductor chips including through silicon vias (TSVs) and semiconductor packages in which the semiconductor chips are stacked. In a semiconductor package including directly bonded stacked semiconductor chips, there is a need to secure the reliability of the bonding between semiconductor chips.

### SUMMARY

The present disclosure provides improved reliability of a semiconductor package through homogeneous bonding in direct bonding between semiconductor chips.

In addition, the technical goals to be achieved by the present disclosure are not limited to the technical goals mentioned above, and other technical goals may be clearly understood by one of ordinary skill in the art from the following descriptions.

According to an aspect of the disclosure, a semiconductor package includes: a first semiconductor chip comprising a first semiconductor substrate and a first via electrode passing through at least a portion of the first semiconductor substrate; a second semiconductor chip on the first semiconductor chip and comprising a second semiconductor substrate; a first bonding pad structure between the first semiconductor chip and the second semiconductor chip; a first dummy bonding pad structure between the first semiconductor chip and the second semiconductor chip; and a first inter-chip insulation layer on a surface of the first semiconductor chip, and a second inter-chip insulation layer on a surface of the second semiconductor chip, in which the first bonding pad structure comprises: a first bonding pad on the surface of the first semiconductor chip, and a second bonding pad on the surface of the second semiconductor chip, in which the first dummy bonding pad structure comprises: a first dummy bonding pad on the surface of the first semiconductor chip, and a second dummy bonding pad on the surface of the second semiconductor chip, in which the second bonding pad and the first bonding pad are in contact with each other and directly bonded to each other, and in which the second dummy bonding pad and the first dummy bonding pad are in contact with each other and directly bonded to each other, and at least a portion of the first inter-chip insulation layer and the second inter-chip insulation layer are in contact with each other and directly bonded to each other.

According to an aspect of the disclosure, a semiconductor package includes: a first semiconductor chip comprising a first semiconductor substrate and a first via electrode passing through at least a portion of the first semiconductor substrate; a second semiconductor chip on the first semiconductor chip and comprising a second semiconductor substrate and a second via electrode passing through at least a portion of the second semiconductor substrate; a first bonding pad structure between the first semiconductor chip and the second semiconductor chip; a first dummy bonding pad structure between the first semiconductor chip and the second semiconductor chip; a second dummy bonding pad structure between the first semiconductor chip and the second semiconductor chip; a first inter-chip insulation layer on a surface of the first semiconductor chip; a second inter-chip insulation layer on a surface of the second semiconductor chip; and an encapsulation member on the first semiconductor chip and surrounding the second semiconductor chip, in which the first bonding pad structure comprises: a first bonding pad on the surface of the first semiconductor chip, and a second bonding pad on the surface of the second semiconductor chip, in which the first dummy bonding pad structure comprises: a first dummy bonding pad on the surface of the first semiconductor chip, and a second dummy bonding pad on the surface of the second semiconductor chip, in which the second dummy bonding pad structure comprises: a third dummy bonding pad on the surface of the first semiconductor chip, and a fourth dummy bonding pad on the surface of the second semiconductor chip, in which the second bonding pad and the first bonding pad are in contact with each other and directly bonded to each other, in which the second dummy bonding pad and the first dummy bonding pad are in contact with each other and directly bonded to each other, in which at least a portion of the first inter-chip insulation layer and the second inter-chip insulation layer are in contact with each other and directly bonded to each other, in which a shape of the first semiconductor chip is larger than a shape of the second semiconductor chip, and in which one surface of the fourth dummy bonding pad is aligned in a direction with a second chip perimeter of the second semiconductor chip, wherein the direction is perpendicular to the surface of the second semiconductor chip.

According to an aspect of the disclosure, a semiconductor package includes: a first semiconductor chip comprising a first semiconductor substrate and a first via electrode passing through at least a portion of the first semiconductor substrate; a second semiconductor chip on the first semiconductor chip and comprising a second semiconductor substrate and a second via electrode passing through at least a portion of the second semiconductor substrate; a first bonding pad structure between the first semiconductor chip and the second semiconductor chip; a first dummy bonding pad structure between the first semiconductor chip and the second semiconductor chip; a second dummy bonding pad structure between the first semiconductor chip and the second semiconductor chip; a third dummy bonding pad structure between the first semiconductor chip and the second semiconductor chip; a first inter-chip insulation layer on a surface of the first semiconductor chip, and a second inter-chip insulation layer on a surface of the second semiconductor chip; and an encapsulation member on the first semiconductor chip and surrounding the second semiconductor chip, in which the first bonding pad structure comprises: a first bonding pad on the surface of the first semiconductor chip, and a second bonding pad on the surface of the second semiconductor chip, in which the first dummy bonding pad structure comprises: a first dummy bonding pad on the surface of the first semiconductor chip, and a second dummy bonding pad on the surface of the second semiconductor chip, in which the second dummy bonding pad structure comprises: a third dummy bonding pad on the surface of the first semiconductor chip, and a fourth dummy bonding pad on the surface of the second semiconductor chip, in which the third dummy bonding pad structure comprises: a fifth dummy bonding pad on the surface of the first semiconductor chip and a sixth dummy bonding pad on the surface of the second semiconductor chip, in which the second bonding pad and the first bonding pad are in contact with each other and directly bonded to each other, in which the second dummy bonding pad and the first dummy bonding pad are in contact with each other and directly bonded to each other, in which at least a portion of the first inter-chip insulation layer and the second inter-chip insulation layer are in contact with each other and directly bonded to each other, in which a shape of the first semiconductor chip is larger than a shape of the second semiconductor chip, in which one surface of the fourth dummy bonding pad is aligned in a direction with a second chip perimeter of the second semiconductor chip, wherein the direction is perpendicular to the surface of the second semiconductor chip, in which the second bonding pad, the second dummy bonding pad, the fourth dummy bonding pad, and the first inter-chip insulation layer do not contact each other, in which the first bonding pad, the first dummy bonding pad, the third dummy bonding pad, and the first inter-chip insulation layer do not contact each other, in which the fourth dummy bonding pad is in contact with a portion of the third dummy bonding pad, and a remaining portion of the third dummy bonding pad is in contact with the encapsulation member, in which the first semiconductor chip comprises a buffer chip and the second semiconductor chip comprises a memory chip, in which the first bonding pad structure connects the first semiconductor chip and the second semiconductor chip to each other, in which each of the first dummy bonding pad structure, the second dummy bonding pad structure, and the third dummy bonding pad structure is not connected to the first semiconductor chip and the second semiconductor chip, in which at least a portion of the third dummy bonding pad structure is within a first region, and in which the first region is defined as a region between the first semiconductor chip and the second semiconductor chip, the first region comprising the first bonding pad structure and not comprising the second dummy bonding pad structure.

### BRIEF DESCRIPTION OF DRAWINGS

Embodiments of the present disclosure will be more clearly understood from the following detailed description taken in conjunction with the accompanying diagrams in which:

FIG. 1 is a cross-sectional view of a semiconductor package according to embodiments;

FIG. 2 is an enlarged cross-sectional view of a portion A of FIG. 1 according to embodiments;

FIG. 3 is a cross-sectional view taken along a portion B-B′ of FIG. 1, in a plan view according to embodiments;

FIG. 4 is a cross-sectional view of a portion of a semiconductor package, the portion being identical to the portion B-B′ of FIG. 1 according to embodiments;

FIG. 5 is a cross-sectional view of a portion of a semiconductor package, the portion being identical to the portion B-B′ of FIG. 1 according to embodiments;

FIG. 6 is a cross-sectional view of a portion of a semiconductor package, the portion being identical to the portion B-B′ of FIG. 1 according to embodiments;

FIG. 7 is a cross-sectional view of a portion of a semiconductor package, the portion being identical to the portion B-B′ of FIG. 1 according to embodiments;

FIG. 8 is a cross-sectional view of a portion of a semiconductor package, the portion being identical to the portion B-B′ of FIG. 1 according to embodiments;

FIG. 9 is a cross-sectional view of a portion of a semiconductor package, the portion being identical to the portion B-B′ of FIG. 1 according to embodiments;

FIG. 10 is a cross-sectional view of a portion of a semiconductor package, the portion being identical to the portion B-B′ of FIG. 1 according to embodiments;

FIG. 11 is a cross-sectional view of a semiconductor package according to embodiments;

FIG. 12 is an enlarged cross-sectional view of a portion D of FIG. 11 according to embodiments; and

FIG. 13 is a cross-sectional view taken along a portion E-E′ of FIG. 11, in a plan view according to embodiments.

### DETAILED DESCRIPTION OF EMBODIMENTS

It will be understood that, although the terms first, second, third, fourth, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

A layer may be described as having an upper surface and a lower surface. As understood by one of ordinary skill in the art, the surfaces of a layer may also be described as first and second surfaces, where a first surface may be one of the upper surface and the lower surface of the layer, and the second surface may be the other of the upper surface and the lower surface of the layer.

The specification uses the terms of degree including “substantially” or “about.” In one or more examples, when specifying that a parameter X may be substantially the same as parameter Y, the term “substantially” may be understood as X being within 10% of Y. In one or more examples, when specifying that a parameter is about X, the term “about” may be understood as being within 10% of X.

In one or more examples, a bonding pad that comprises a plurality of bonding pads such as a lower bonding pad (e.g., first bonding pad) and an upper bonding pad (e.g., second bonding pad) may be referred to as a bonding pad structure.

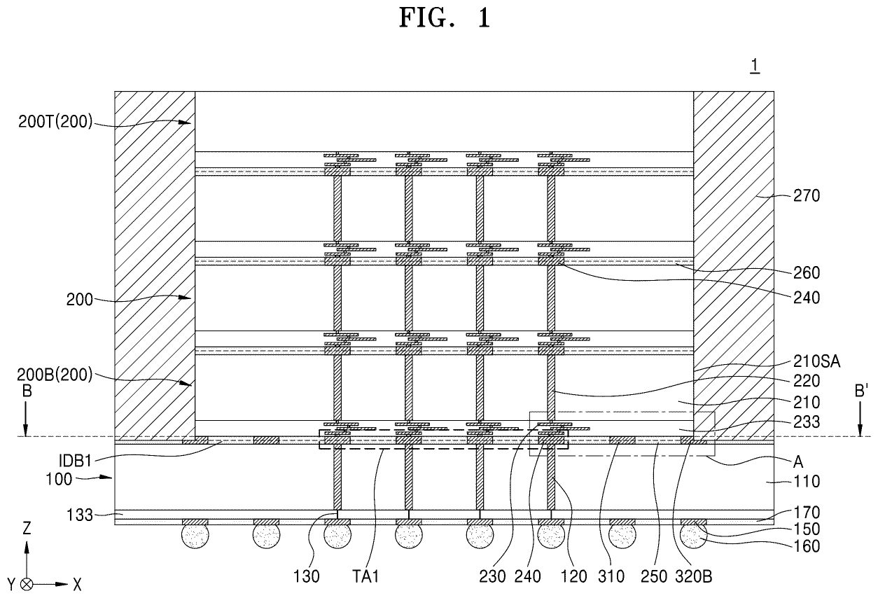

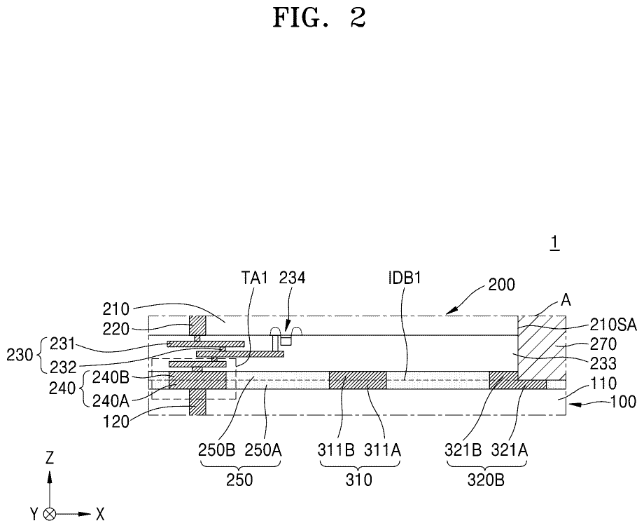

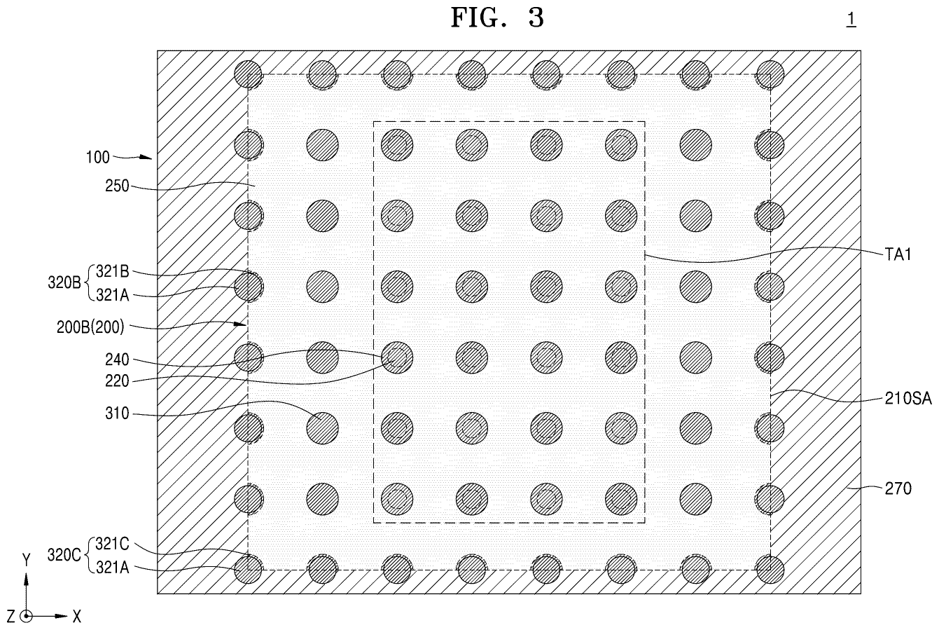

FIG. 1 is a cross-sectional view of a semiconductor package 1 according to embodiments. FIG. 2 is an enlarged cross-sectional view of a portion A of FIG. 1. FIG. 3 is a cross-sectional view taken along a portion B-B′ of FIG. 1, in a plan view.

Referring to FIGS. 1 to 3, the semiconductor package 1 according to embodiments may include a first semiconductor chip 100, a plurality of second semiconductor chips 200 stacked on the first semiconductor chip 100, and an encapsulation member 270 surrounding the plurality of second semiconductor chips 200 on the first semiconductor chip 100. From among the plurality of second semiconductor chips 200, the one closest to the first semiconductor chip 100 may be referred to as a lowermost second semiconductor chip 200B, and, from among the plurality of second semiconductor chips 200, the one located farthest from the first semiconductor chip 100 may be referred to as an uppermost second semiconductor chip 200T.

The shape of the first semiconductor chip 100 in a plan view may be larger than the shape of the second semiconductor chip 200 in a plan view. For example, as illustrated in FIG. 2, the first semiconductor chip 100 has a length in the X direction that is greater than a length of the second semiconductor chip 200 in the X direction. As shown in FIG. 3, the shape of the plurality of second semiconductor chips 200 in a plan view may be positioned inside the shape of the first semiconductor chip 100 in a plan view. For example, a planar shape of the lowermost second semiconductor chip 200B in a plan view may be positioned inside the shape of the first semiconductor chip 100 in a plan view. The semiconductor package 1 may be manufactured through a wafer-on-chip (CoW) process. However, as understood by one of ordinary skill in the art, the embodiments of the present disclosure are not limited these configurations.

In one or more examples, the plurality of second semiconductor chips 200 may all be the same type of memory chips. The memory chip may be a volatile memory chip such as dynamic random access memory (DRAM) or static random access memory (SRAM) or a non-volatile memory chip such as phase-change random access memory (PRAM), magneto-resistive random access memory (MRAM), ferroelectric random access memory (FeRAM), resistive random access memory (RRAM), or any other suitable memory structure known to one of ordinary skill in the art.

For example, the plurality of second semiconductor chips 200 may each be a memory chip such as a dynamic random access memory (DRAM) chip. For example, the plurality of second semiconductor chips 200 may be chips of the same type. For example, the semiconductor package 1 including the first semiconductor chip 100 and the plurality of second semiconductor chips 200 may be a high bandwidth memory (HBM), wherein the first semiconductor chip 100 may be referred to as an HBM controller die, and the plurality of second semiconductor chips 200 may each be referred to as a DRAM die. In one or more examples, a HBM may be a computer memory optimized for fast data transfer and reduced power consumption. HBMs may deploy DRAM dies stacked vertically using through-silicon vias.

According to some embodiments, the first semiconductor chip 100 may include a serial-parallel conversion circuit that parallelizes data signals received from a controller chip and transmits parallelized data signals to a memory chip, and may be a buffer chip for controlling a second semiconductor chip 200. The first semiconductor chip 100 may also be referred to as an interface die, a base die, a logic die, a master die, etc. According to some embodiments, the second semiconductor chip 200 may be a memory chip including memory cells.

The semiconductor package 1 may include the plurality of second semiconductor chips 200. Each semiconductor chip in the plurality of second semiconductor chips 200 may have the same size in a plan view. For example, the widths of the plurality of second semiconductor chips 200 may be substantially identical to one another. The plurality of second semiconductor chips 200 excluding the uppermost second semiconductor chip 200T may have substantially the same thickness. For example, sidewalls of the plurality of second semiconductor chips 200 may be aligned perpendicular to each other. In one or more examples, at least one of the second semiconductor chips 200 may have dimensions that are different than other second semiconductor chips 200.

FIG. 2 illustrates an example structure of a second semiconductor chip 200. The semiconductor chip 200 illustrated in FIG. 2 may correspond to each of the second semiconductor chips 200 illustrated in FIG. 1. The second semiconductor chip 200 may include a second semiconductor substrate 210, a second via electrode 220 vertically penetrating through at least a portion of the second semiconductor substrate 210, a second semiconductor device 234 provided on one surface of the second semiconductor substrate 210, a second front insulation layer 233 disposed on the front surface (or lower surface) of the second semiconductor substrate 210 and covering the second semiconductor device 234, a second wiring pattern 230 provided in the second front insulation layer 233, a first upper bonding pad 240B disposed on the second front insulation layer 233, a first upper dummy bonding pad 311B disposed on the second front insulation layer 233, a second upper dummy bonding pad 321B and a third upper dummy bonding pad 321C arranged on the second front insulation layer 233, and a first upper inter-chip insulation layer 250B disposed on the bottom surface of the second front insulation layer 233.

The first semiconductor chip 100 may include a first semiconductor substrate 110, a first via electrode 120 vertically penetrating through at least a portion of the first semiconductor substrate 110, a first semiconductor device provided on one surface of the first semiconductor substrate 110, a first front insulation layer 133 disposed on the front surface (or lower surface) of the first semiconductor substrate 110, a first wiring pattern 130 provided in the first front insulation layer 133, a first lower inter-chip insulation layer 250A provided on the top surface of the first semiconductor substrate 110, a first lower bonding pad 240A provided on the top surface of the first semiconductor substrate 110, a first lower dummy bonding pad 311A, a second lower dummy bonding pad 321A, a first front pad 150 disposed on the bottom surface of the first semiconductor chip 100, and a first lower passivation layer 170 provided on the bottom surface of the first semiconductor chip 100 and surrounding a portion of the first front pad 150.

The first semiconductor substrate 110 and the second semiconductor substrate 210 may include a semiconductor material such as silicon (Si). In one or more examples, the first semiconductor substrate 110 and the second semiconductor substrate 210 may include a semiconductor material such as germanium (Ge). The first semiconductor substrate 110 and the second semiconductor substrate 210 may each include a conductive region (e.g., a well doped with impurities, on its active surface). The first semiconductor substrate 110 and the second semiconductor substrate 210 may have various device isolation structures such as a shallow trench isolation (STI) structure.

The first semiconductor chip 100 may include the first via electrode 120 penetrating through at least a portion of the first semiconductor substrate 110. The first via electrode 120 may electrically connect the first front pad 150 and the first lower bonding pad 240A. The first semiconductor chip 100 may further include the first lower passivation layer 170 disposed on the bottom surface of the first semiconductor chip 100. The first front pad 150 may be surrounded by the first lower passivation layer 170. The first front pad 150 may be electrically connected to a first semiconductor device layer. The first semiconductor device layer may include an insulation layer and the first wiring pattern 130. An external connection terminal 160 may be provided on the first front pad 150. The first wiring pattern 130 of the first semiconductor chip 100 is illustrated in a simplified form with solid lines.

A first bonding pad 240 and a second inter-chip insulation layer 260 may be provided between second semiconductor chips 200 adjacent to each other from among the plurality of second semiconductor chips 200. The first bonding pad 240 and the second inter-chip insulation layer 260 provided between second semiconductor chips 200 adjacent to each other may be formed through direct bonding as described below.

The first semiconductor chip 100 and the second semiconductor chip 200 may be directly bonded to each other. Direct bonding between two chips may include direct bonding between conductive components of the two chips facing each other and direct bonding between insulation components of the two chips facing each other. Direct bonding between insulation components may involve the formation of a chemical bond between the insulation components. Direct bonding between any two chips may include hybrid bonding. In one or more examples, hybrid bonding may be a bond that combine a dielectric bond (e.g., SiOx) with embedded metal (e.g., Cu) to form interconnections.

In one or more examples, the first lower bonding pad 240A provided on the top surface of the first semiconductor substrate 110 of the first semiconductor chip 100 and the first upper bonding pad 240B disposed on the second front insulation layer 233 of the second semiconductor chip 200 may be directly bonded to each other. The first lower dummy bonding pad 311A provided on the top surface of the first semiconductor substrate 110 of the first semiconductor chip 100 and the first upper dummy bonding pad 311B disposed on the second front insulation layer 233 of the second semiconductor chip 200 may be directly bonded to each other. The second lower dummy bonding pad 321A provided on the top surface of the first semiconductor substrate 110 of the first semiconductor chip 100 and the second upper dummy bonding pad 321B disposed on the second front insulation layer 233 of the second semiconductor chip 200 may be directly bonded to each other. As shown in FIG. 3, the second lower dummy bonding pad 321A and the third upper dummy bonding pad 321C disposed on the second front insulation layer 233 of the second semiconductor chip 200 may be directly bonded to each other.

For example, the first lower inter-chip insulation layer 250A provided on the top surface of the first semiconductor substrate 110 of the first semiconductor chip 100 and the first upper inter-chip insulation layer 250B provided on the bottom surface of the second front insulation layer 233 of the second semiconductor chip 200 may be directly bonded to each other. The first lower inter-chip insulation layer 250A and the first upper inter-chip insulation layer 250B may include the same material. For example, the first lower inter-chip insulation layer 250A and the first upper inter-chip insulation layer 250B may include silicon oxide. A direct bonding process may be performed through a high-temperature annealing process while the first lower inter-chip insulation layer 250A and the first upper inter-chip insulation layer 250B are in direct contact with each other. A dielectric material constituting the first lower inter-chip insulation layer 250A and the first upper inter-chip insulation layer 250B is not limited to silicon oxide and may be materials that may be bonded to each other. For example, the dielectric material may include silicon carbon nitride (SiCN).

The first lower inter-chip insulation layer 250A may be provided on the top surface of the first semiconductor chip 100 to substantially match the shape of the second semiconductor chip 200 in a plan view, or the first lower inter-chip insulation layer 250A may be provided on the top surface of the first semiconductor chip 100 to have a planar area larger than that of the second semiconductor chip 200. The first lower inter-chip insulation layer 250A may be provided on the top surface of the first semiconductor chip 100 to have a size equal to or smaller than that of the shape of the first semiconductor chip 100 in a plan view. The shape of the first upper inter-chip insulation layer 250B in a plan view may be included within the shape of the first lower inter-chip insulation layer 250A in a plan view, or the shape of the first lower inter-chip insulation layer 250A in a plan view may be substantially identical to the shape of the first upper inter-chip insulation layer 250B in a plan view.

During the direct bonding process, for example, metal atoms in the first lower bonding pad 240A provided on the top surface of the first semiconductor substrate 110 of the first semiconductor chip 100 may diffuse into the first upper bonding pad 240B disposed on the second front insulation layer 233 of the second semiconductor chip 200, and metal atoms in the first upper bonding pad 240B may diffuse into the first lower bonding pad 240A. Therefore, the interface between the first upper bonding pad 240B and the first lower bonding pad 240A may not be distinguished. However, for the purpose of distinction, the interface is indicated by a dotted line in FIGS. 1 and 2. In one or more examples, a direct boding process between two components may include component preprocessing, pre-bonding at room temperature, and annealing at elevated temperatures.

Through the direct bonding process, the first upper bonding pad 240B and the first lower bonding pad 240A may be firmly bonded. This may be referred to as direct bonding between the first upper bonding pad 240B and the first lower bonding pad 240A. The first upper bonding pad 240B and the first lower bonding pad 240A that are directly bonded may be collectively referred to as the first bonding pad 240. The first lower dummy bonding pad 311A and the first upper dummy bonding pad 311B that are directly bonded may be collectively referred to as a first dummy bonding pad 310. The second lower dummy bonding pad 321A and the second upper dummy bonding pad 321B that are directly bonded may be collectively referred to as a second dummy bonding pad 320B. As shown in FIG. 3, the second lower dummy bonding pad 321A and the third upper dummy bonding pad 321C that are directly bonded may be collectively referred to as a third dummy bonding pad 320C.

The first dummy bonding pad 310, the second dummy bonding pad 320B, and the third dummy bonding pad 320C may not be electrically connected to the first semiconductor chip 100 and the second semiconductor chip 200. The first dummy bonding pad 310, the second dummy bonding pad 320B, and the third dummy bonding pad 320C may not be electrically connected to the plurality of first via electrodes 120 and the plurality of second via electrodes 220. In one or more examples, the first dummy bonding pad 310, the second dummy bonding pad 320B, and the third dummy bonding pad 320C may not be electrically connected to the second semiconductor device 234. In one or more examples, the first dummy bonding pad 310, the second dummy bonding pad 320B, and the third dummy bonding pad 320C may be electrically connected to only one of the first semiconductor chip 100 and the second semiconductor chip 200.

During the direct bonding process, the first lower inter-chip insulation layer 250A and the first upper inter-chip insulation layer 250B may be in direct contact and be connected through direct bonding. For example, a chemical bond may be provided between the first lower inter-chip insulation layer 250A and the first upper inter-chip insulation layer 250B. The chemical bond may be a covalent bond. After direct bonding, the interface between the first lower inter-chip insulation layer 250A and the first upper inter-chip insulation layer 250B may not be distinguished. However, for the purpose of distinction, the interface is indicated by a dotted line in FIGS. 1 and 2. The first lower inter-chip insulation layer 250A and the first upper inter-chip insulation layer 250B that are directly bonded may be collectively referred to as a first inter-chip bonding insulation layer 250.

The second front insulation layer 233 is provided on the bottom surface of the second semiconductor substrate 210 and may cover the second semiconductor device 234. The second front insulation layer 233 may include a silicon-based insulation material. The silicon-based insulation material may include, for example, silicon oxide, silicon nitride, silicon oxynitride, and/or tetraethyl orthosilicate (TEOS). The second front insulation layer 233 may include a plurality of stacked layers.

The second semiconductor device 234 may be provided on one surface of the second semiconductor substrate 210. The second semiconductor device 234 may each include a plurality of individual devices of various types. The plurality of individual devices may include various microelectronic devices (e.g., a metal-oxide-semiconductor field effect transistor (MOSFET)) such as a complementary metal-insulator-semiconductor transistor (CMOS transistor), a system large scale integration (LSI), a micro-electro-mechanical system (MEMS), an active device, a passive device, etc.

The second wiring pattern 230 may be provided within the second front insulation layer 233. The second wiring pattern 230 may include a second line pattern 231 and a second via pattern 232. For example, the second wiring pattern 230 may be a multi-layered wiring in which two or more second line patterns 231 and/or two or more second via patterns 232 are alternately stacked.

The second wiring pattern 230 may be electrically connected to at least one of the second semiconductor device 234 and the second via electrode 220. As used herein, electrical connection includes direct connection or indirect connection via another conductive component. Being electrically connected to a semiconductor chip may mean being electrically connected to integrated circuits of the semiconductor chip. A component being connected to through vias and/or integrated circuits may mean that the component is electrically connected to at least one of through vias and integrated circuits.

The encapsulation member 270 may surround the second semiconductor chip 200 on the top surface of the first semiconductor chip 100. The encapsulation member 270 may include, for example, an epoxy mold compound (EMC). The encapsulation member 270 may further include filler. In one or more examples, the encapsulation member 270 may be formed of one or more materials that safeguards semiconductor chips from harms from the external environment such as moisture. The encapsulation member may be formed of plastic (e.g., epoxy molding compounds, silicones, polyurethanes), metal (e.g., Kovar), or ceramic.

The boundary formed by side surfaces of the second semiconductor chip 200 may be referred to as a second chip perimeter 210SA. The second chip perimeter 210SA may be included in a surface where the plurality of second semiconductor chips 200 are aligned in a vertical direction. As shown in FIG. 2, at least a portion of the second chip perimeter 210SA may be in contact with the encapsulation member 270. Some of side surfaces of the second upper dummy bonding pad 321B and the third upper dummy bonding pad 321C may be in contact with the encapsulation member 270.

The second lower dummy bonding pad 321A may be placed on the top surface of the first semiconductor chip 100 and at the lower end of the outer edge of the second semiconductor chip 200. A portion of the second lower dummy bonding pad 321A may be located inside the second chip perimeter 210SA of the second semiconductor chip 200, and the remaining portion of the second lower dummy bonding pad 321A may be located outside the second chip perimeter 210SA. In one or more examples, a portion of the second lower dummy bonding pad 321A may have a shape that protrudes from the second chip perimeter 210SA toward the outer edge of the first semiconductor chip 100.

The second upper dummy bonding pad 321B and the third upper dummy bonding pad 321C may be provided adjacent to the outer edge of the second semiconductor chip 200, but the second upper dummy bonding pad 321B and the third upper dummy bonding pad 321C may be positioned inside the second chip perimeter 210SA. Unlike the second lower dummy bonding pad 321A, the second upper dummy bonding pad 321B and the third upper dummy bonding pad 321C may not protrude outside the second chip perimeter 210SA.

The second upper dummy bonding pad 321B and the third upper dummy bonding pad 321C may each be in contact with a portion of the second lower dummy bonding pad 321A. The second lower dummy bonding pad 321A excluding a portion of the second lower dummy bonding pad 321A in contact with the second upper dummy bonding pad 321B may be in contact with the encapsulation member 270 without being in contact with the second upper dummy bonding pad 321B. The second lower dummy bonding pad 321A excluding a portion of the second lower dummy bonding pad 321A in contact with the third upper dummy bonding pad 321C may be in contact with the encapsulation member 270 without being in contact with the third upper dummy bonding pad 321C.

In a plan view, the second upper dummy bonding pad 321B may have a shape substantially identical to a portion of the shape of the second lower dummy bonding pad 321A. For example, the second lower dummy bonding pad 321A may have a circular shape in a plan view, and the second upper dummy bonding pad 321B may have an arc shape and a shape connecting both ends of the arc or a semicircular shape in a plan view. For example, the second lower dummy bonding pad 321A may have a rectangular shape in a plan view, and the second upper dummy bonding pad 321B may have a rectangular shape with a portion of the rectangular shape of the second lower dummy bonding pad 321A removed in a plan view.

In a plan view, the third upper dummy bonding pad 321C may have a shape substantially identical to a portion of the shape of the second lower dummy bonding pad 321A. For example, the second lower dummy bonding pad 321A may have a circular shape in a plan view, and the third upper dummy bonding pad 321C may have a quadrant shape in a plan view. For example, the second lower dummy bonding pad 321A may have a rectangular shape in a plan view, and the third upper dummy bonding pad 321C may have a rectangular shape with a portion of the rectangular shape of the second lower dummy bonding pad 321A removed in a plan view.

For example, as shown in FIG. 3, a plurality of second dummy bonding pads 320B may be arranged along the second chip perimeter 210SA. A plurality of third dummy bonding pads 320C may be arranged at vertices, which are bent portions of the second chip perimeter 210SA. In FIG. 3, the second upper dummy bonding pad 321B and the third upper dummy bonding pad 321C are indicated by dotted lines, and the second lower dummy bonding pad 321A is indicated by a solid line.

For example, a plurality of second lower dummy bonding pads 321A may be arranged on the top surface of the first semiconductor chip 100 along the second chip perimeter 210SA. In one or more examples, the plurality of second lower dummy bonding pads 321A may be arranged, such that the second chip perimeter 210SA overlaps with the plurality of second lower dummy bonding pads 321A. Second upper dummy bonding pads 321B may be arranged along the second chip perimeter 210SA. In one or more examples, the second upper dummy bonding pads 321B may be arranged to not to deviate from the inner side of the second chip perimeter 210SA. Third upper dummy bonding pads 321C may be positioned at vertices of the second chip perimeter 210SA, but the third upper dummy bonding pads 321C may be positioned to not to deviate from the inner side of the second chip perimeter 210SA.

The shape of the second upper dummy bonding pad 321B in a plan view may substantially coincide with a portion of the shape of the second lower dummy bonding pad 321A in a plan view. Therefore, when the second upper dummy bonding pad 321B and the second lower dummy bonding pad 321A are directly bonded, a portion of the second lower dummy bonding pad 321A that does not match the second upper dummy bonding pad 321B may not contact the second upper dummy bonding pad 321B. Therefore, the encapsulation member 270 may contact the portion of the second lower dummy bonding pad 321A that does not match the second upper dummy bonding pad 321B.

The shape of the third upper dummy bonding pad 321C in a plan view may substantially coincide with a portion of the shape of the second lower dummy bonding pad 321A in a plan view. Therefore, when the third upper dummy bonding pad 321C and the second lower dummy bonding pad 321A are directly bonded, a portion of the second lower dummy bonding pad 321A that does not match the third upper dummy bonding pad 321C may not contact the third upper dummy bonding pad 321C. Therefore, the encapsulation member 270 may contact the portion of the second lower dummy bonding pad 321A that does not match the third upper dummy bonding pad 321C.

The first dummy bonding pad 310 may include the first upper dummy bonding pad 311B provided on the bottom surface of the second semiconductor chip 200 and the first lower dummy bonding pad 311A provided on the top surface of the first semiconductor chip 100. In a plan view, the shape of the first upper dummy bonding pad 311B may substantially match the shape of the first lower dummy bonding pad 311A. Therefore, the entire bottom surface of the first upper dummy bonding pad 311B and the entire bottom surface of the first lower dummy bonding pad 311A may be in contact with each other.

The first bonding pad 240, the first dummy bonding pad 310, the second dummy bonding pad 320B, and the third dummy bonding pad 320C provided between the first semiconductor chip 100 and the second semiconductor chip 200 may not contact the first inter-chip bonding insulation layer 250 at a first direct bonding interface IDB1. The first direct bonding interface IDB1 may refer to the interface formed between the first semiconductor chip 100 and the second semiconductor chip 200 before the first semiconductor chip 100 and the second semiconductor chip 200 are integrated by direct bonding. Therefore, the first direct bonding interface IDB1 may be understood as a plane that passes through approximately half the thickness of each component after direct bonding, and the first direct bonding interface IDB1 may be understood as a virtual interface that is not observed after direct bonding is performed.

For example, the first direct bonding interface IDB1 may refer to an extended surface of a surface where the first upper bonding pad 240B and the first lower bonding pad 240A are in contact with each other, a surface where the first upper dummy bonding pad 311B and the first lower dummy bonding pad 311A are in contact with each other, a surface where the first upper dummy bonding pad 311B and the first lower dummy bonding pad 311A are in contact with each other, a surface where the second upper dummy bonding pad 321B and the second lower dummy bonding pad 321A are in contact with each other, a surface where the third upper dummy bonding pad 321C and the second lower dummy bonding pad 321A are in contact with each other, and a surface where the first upper inter-chip insulation layer 250B and the first lower inter-chip insulation layer 250A are in contact with each other, immediately before the direct bonding process is performed.

In the semiconductor package 1, according to embodiments, components that are directly bonded between the first semiconductor chip 100 and the second semiconductor chip 200 are not hetero-bonded. In other words, in the semiconductor package 1 according to embodiments, components that are directly bonded between the first semiconductor chip 100 and the second semiconductor chip 200 may be homogenously bonded.

In one or more examples, hetero-bonding may refer to a direct bonding process that is performed while different categories of materials are in contact with each other. For example, the hetero-bonding may refer to a direct bonding process that is performed, at a direct bonding interface, in a state where a metal component and a non-metal component are in direct contact at a direct bonding interface. In one or more examples, homogenous bonding may refer to a direct bonding process that is performed while the same categories of materials are in contact with each other. For example, the homogeneous bonding may refer to a direct bonding process that is performed, at a direct bonding interface, in which a metal component is in direct contact with a metal component, or a non-metal component is in direct contact with a non-metal component.

In one or more examples, the hetero-bonding may mean that at least a portion of the first upper bonding pad 240B, at least a portion of the first upper dummy bonding pad 311B, at least a portion of the second upper dummy bonding pad 321B, or at least a portion of the third upper dummy bonding pad 321C is directly bonded to the first lower inter-chip insulation layer 250A while in contact with the first lower inter-chip insulation layer 250A. In one or more examples, the hetero-bonding may include a case in which at least a portion of the first lower bonding pad 240A, at least a portion of the first lower dummy bonding pad 311A, or at least a portion of the second lower dummy bonding pad 321A is directly bonded to the first upper inter-chip insulation layer 250B while in contact with the first upper inter-chip insulation layer 250B.

In one or more examples, the homogeneous bonding may include direct bonding of the first upper bonding pad 240B, the first upper dummy bonding pad 311B, the second upper dummy bonding pad 321B, and the third upper dummy bonding pad 321C without contacting the first lower inter-chip insulation layer 250A. In one or more examples, the homogeneous bonding may include direct bonding of the first lower bonding pad 240A, the first lower dummy bonding pad 311A, or the second lower dummy bonding pad 321A without contacting the first upper inter-chip insulation layer 250B.

In the semiconductor package 1, according to embodiments, components that are directly bonded to each other may be homogenously bonded. At the first direct bonding interface IDB1 of FIGS. 1 and 2, the first lower bonding pad 240A may not be in contact with the first upper inter-chip insulation layer 250B, and the first upper bonding pad 240B may not be in contact with the first lower inter-chip insulation layer 250A at the first direct bonding interface IDB1. Similarly, at the first direct bonding interface IDB1, the first lower dummy bonding pad 311A and the second lower dummy bonding pad 321A may not be in contact with the first upper inter-chip insulation layer 250B, and the first upper dummy bonding pad 311B and the second upper dummy bonding pad 321B may not be in contact with the first lower inter-chip insulation layer 250A at the first direct bonding interface IDB1.

In other words, the first lower bonding pad 240A may only contact the first upper bonding pad 240B at the first direct bonding interface IDB1, the first lower dummy bonding pad 311A may only contact the first upper dummy bonding pad 311B at the first direct bonding interface IDB1, and the second upper dummy bonding pad 321B may only contact the second upper dummy bonding pad 321B at the first direct bonding interface IDB1.

In the semiconductor package 1, according to embodiments, components that are directly bonded between the first semiconductor chip 100 and the second semiconductor chip 200 are not hetero-bonded. In other words, in the semiconductor package 1 according to embodiments, components that are directly bonded between the first semiconductor chip 100 and the second semiconductor chip 200 may only be homogenously bonded. In particular, in the second dummy bonding pad 320B and the third dummy bonding pad 320C, the second lower dummy bonding pad 321A and the first upper inter-chip insulation layer 250B are not directly bonded while in contact with each other. Instead, in the semiconductor package 1, the second lower dummy bonding pad 321A and the second upper dummy bonding pad 321B are directly bonded and the second lower dummy bonding pad 321A and the third upper dummy bonding pad 321C are directly bonded, and thus hetero-bonding does not occur at the first direct bonding interface IDB1.

As described above, direct bonding between the first semiconductor chip 100 and the second semiconductor chip 200 may include direct bonding between conductive components and direct bonding between insulation components. In direct bonding, since homogeneous bonding is formed in the semiconductor package 1, the bonding strength of direct bonding between the first semiconductor chip 100 and the second semiconductor chip 200 may be greater than when heterogeneous bonding is performed between the first semiconductor chip 100 and the second semiconductor chip 200. In the semiconductor package 1 in which components are directly bonded by homogeneous bonding, the possibility of defects such as warpage of the semiconductor package 1, peel-off occurring between the first semiconductor chip 100 and the second semiconductor chip 200, or short-circuit between the first semiconductor chip 100 and the second semiconductor chip 200 may be reduced. Therefore, since only homogeneous bonding is performed in direct bonding between semiconductor chips, the reliability of the semiconductor package 1 according to embodiments may be improved.

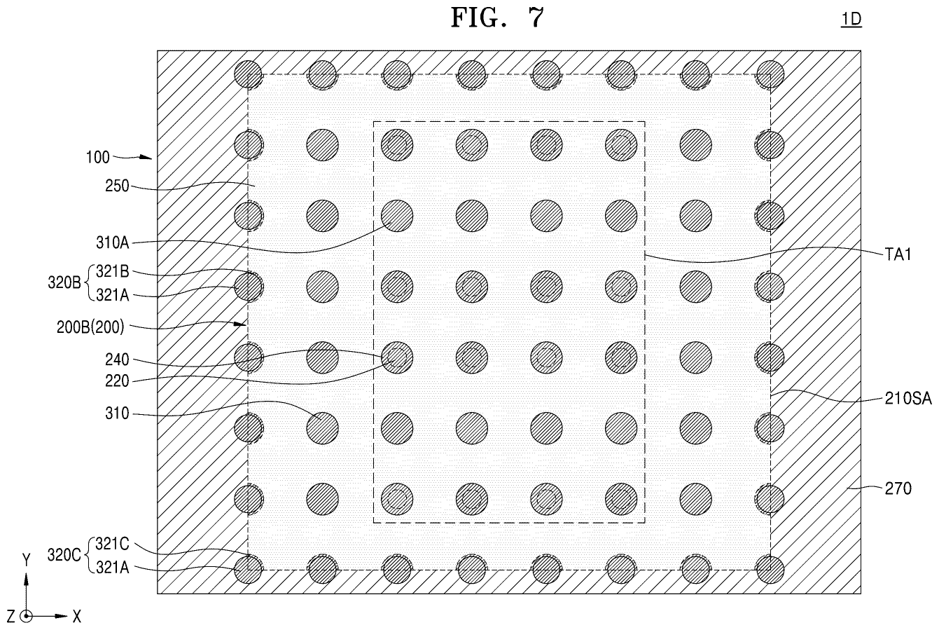

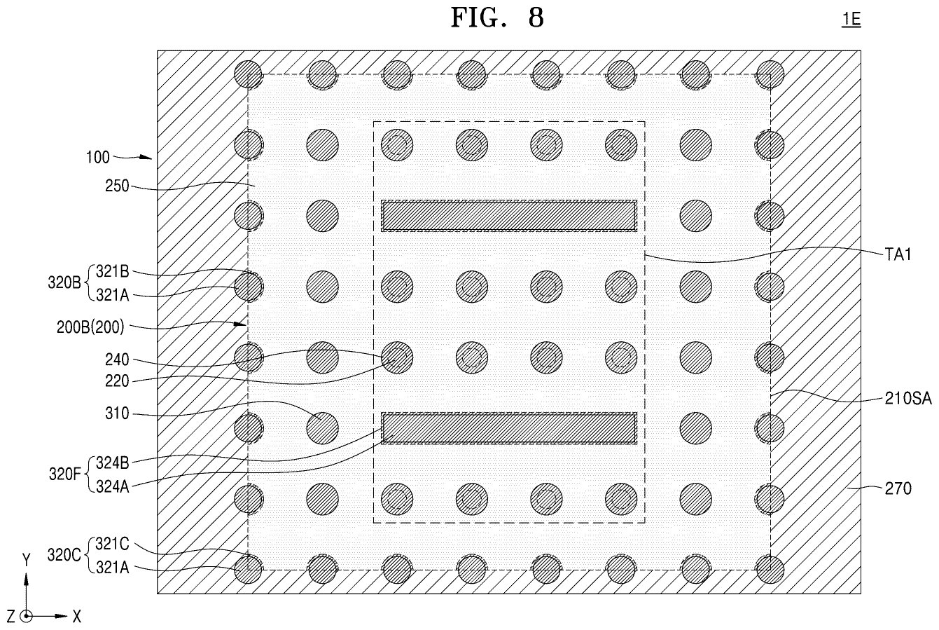

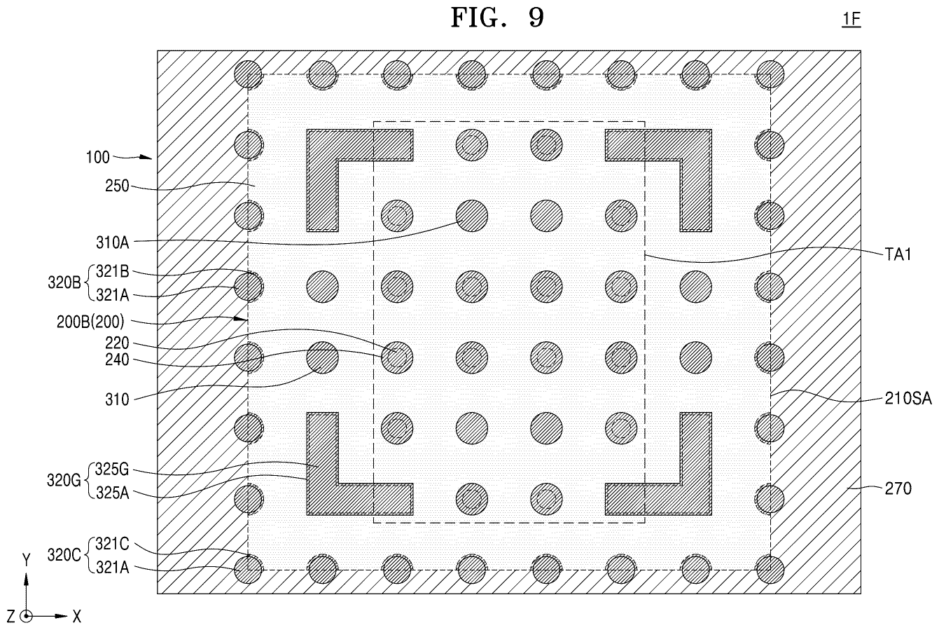

A first region TA1 may be defined as a region including the first bonding pad 240 between the first semiconductor chip 100 and the second semiconductor chip 200. As shown in FIGS. 1 to 3, when the shapes of the first semiconductor chip 100 and the second semiconductor chip 200 in a plan view are rectangular, the shape of the first region TA1 in a plan view may also be rectangular. The first region TA1 may include a first bonding pad 240 therein, and at least a portion of an inner dummy bonding pad 310A described later in FIG. 7, a sixth dummy bonding pad 320F described later in FIG. 8, or a seventh dummy bonding pad 320G described later in FIG. 9 may be included within the first region TA1. Additional descriptions of Area 1 TA1 will be given below with reference to FIGS. 7 to 9.

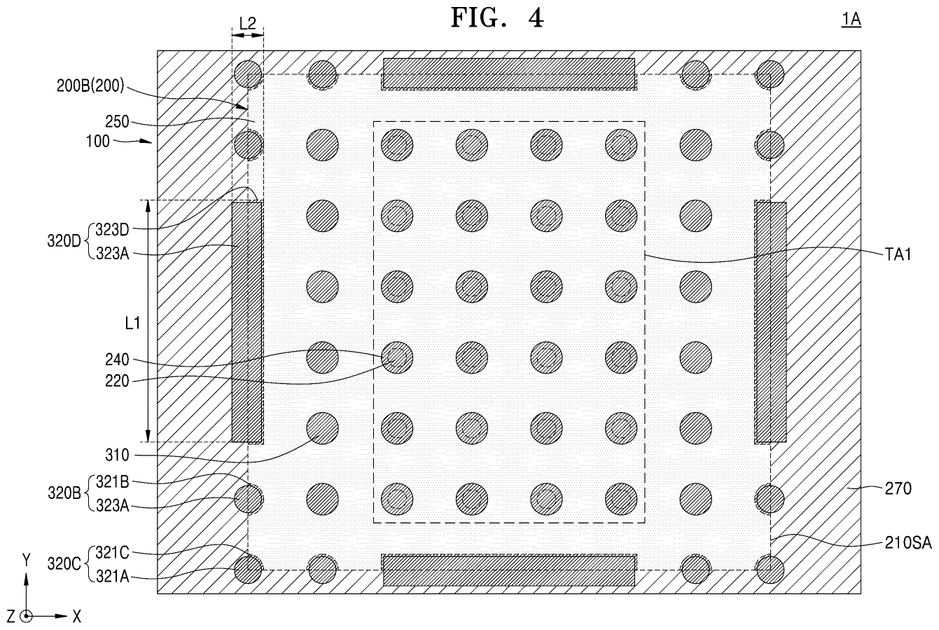

FIG. 4 is a cross-sectional view of a portion of a semiconductor package 1A identical to the portion B-B′ of FIG. 1. Descriptions not given below may be substantially identical to descriptions given above.

Referring to FIG. 4, the second semiconductor chip 200 may further include a fourth upper dummy bonding pad 323D on the bottom surface of the second semiconductor chip 200. The first semiconductor chip 100 may further include a fourth lower dummy bonding pad 323A on the top surface of the first semiconductor chip 100. The fourth upper dummy bonding pad 323D and the fourth lower dummy bonding pad 323A may be directly bonded to each other. The fourth upper dummy bonding pad 323D and the fourth lower dummy bonding pad 323A that are directly bonded to each other may be referred to as a fourth dummy bonding pad 320D. The fourth dummy bonding pad 320D may not be electrically connected to the first semiconductor chip 100 and the second semiconductor chip 200. In one or more examples, the fourth dummy bonding pad 320D may not be electrically connected to the first semiconductor chip 100 or the second semiconductor chip 200.

For example, as shown in FIG. 4, a plurality of fourth dummy bonding pads 320D may be arranged along the second chip perimeter 210SA. The fourth dummy bonding pad 320D may have a bar-like shape extending along the second chip perimeter 210SA. In one or more examples, the fourth lower dummy bonding pad 323A and the fourth upper dummy bonding pad 323D may each have a bar-like shape extending along the second chip perimeter 210SA. The fourth upper dummy bonding pad 323D is indicated by a dotted line, and the fourth lower dummy bonding pad 323A is indicated by a solid line.

For example, a plurality of fourth lower dummy bonding pads 323A may be arranged on the top surface of the first semiconductor chip 100 along the second chip perimeter 210SA. In one or more examples, the plurality of fourth lower dummy bonding pads 323A may be arranged, such that the second chip perimeter 210SA overlaps with the plurality of fourth lower dummy bonding pads 323A. The fourth upper dummy bonding pad 323D may be arranged along the second chip perimeter 210SA, but the fourth upper dummy bonding pad 323D may be arranged to not to deviate from the inner side of the second chip perimeter 210SA.

The shape of the fourth upper dummy bonding pad 323D in a plan view may substantially coincide with a portion of the shape of the fourth lower dummy bonding pad 323A in a plan view. Therefore, when the fourth upper dummy bonding pad 323D and the fourth lower dummy bonding pad 323A are directly bonded, a portion of the fourth lower dummy bonding pad 323A that does not match the fourth upper dummy bonding pad 323D may not contact the fourth upper dummy bonding pad 323D. Therefore, the encapsulation member 270 may contact the portion of the fourth lower dummy bonding pad 323A that does not match the fourth upper dummy bonding pad 323D.

The length of the fourth dummy bonding pad 320D in the extending direction of the fourth dummy bonding pad 320D may be referred to as a first length L1, and the length of the fourth dummy bonding pad 320D in the thickness-wise direction based on the length-wise direction may be referred to as a second length L2. The first length L1 may be less than the second length L2. The first length L1 may be, for example, within the range from about 20 μm to about 1 mm. The second length L2 may be, for example, within the range from about 10 μm to about 200 μm. However, the present disclosure is not limited by the numerical values of the first length L1 and the second length L2.

In the semiconductor package 1A in which components are directly bonded by homogeneous bonding, the possibility of defects such as warpage of the semiconductor package 1A, peel-off occurring between the first semiconductor chip 100 and the second semiconductor chip 200, or short-circuit between the first semiconductor chip 100 and the second semiconductor chip 200 may be reduced. In one or more examples, the semiconductor package 1A may have a larger direct bonded portion of homogeneous bonding between the first semiconductor chip 100 and the second semiconductor chip 200 through the fourth dummy bonding pad 320D. Therefore, since only homogeneous bonding is performed in direct bonding between semiconductor chips in the semiconductor package 1A, the reliability of the semiconductor package 1A according to embodiments may be improved.

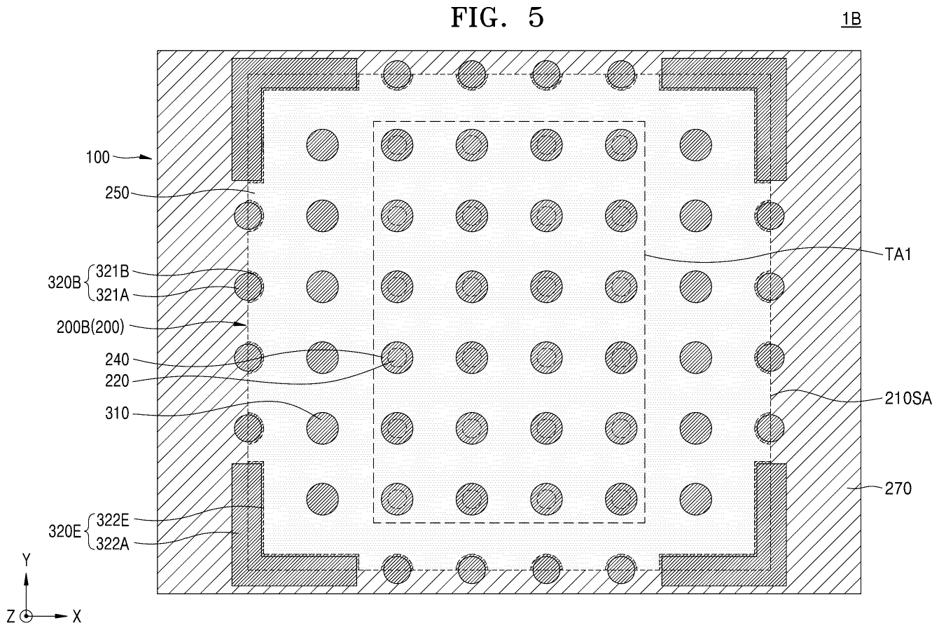

FIG. 5 is a cross-sectional view of a portion of a semiconductor package 1B identical to the portion B-B′ of FIG. 1. Descriptions not given below may be substantially identical to descriptions given above.

Referring to FIG. 5, the second semiconductor chip 200 may further include a fifth upper dummy bonding pad 322E on the bottom surface of the second semiconductor chip 200. The first semiconductor chip 100 may further include a fifth lower dummy bonding pad 322A on the top surface of the first semiconductor chip 100. The fifth upper dummy bonding pad 322E and the fifth lower dummy bonding pad 322A may be directly bonded to each other. The fifth upper dummy bonding pad 322E and the fifth lower dummy bonding pad 322A may be referred to as a fifth dummy bonding pad 320E. The fifth dummy bonding pad 320E may not be electrically connected to the first semiconductor chip 100 and the second semiconductor chip 200. In one or more examples, the fifth dummy bonding pad 320E may not be electrically connected to the first semiconductor chip 100 or the second semiconductor chip 200.

For example, as shown in FIG. 5, a plurality of fifth dummy bonding pads 320E may be arranged along the second chip perimeter 210SA. The fifth dummy bonding pad 320E may extend along the second chip perimeter 210SA, but may have an ‘L-like shape’ that is bent at a portion of the fifth dummy bonding pad 320E. In one or more examples, the fifth lower dummy bonding pad 322A and the fifth upper dummy bonding pad 322E may each extend along the second chip perimeter 210SA, but may have an ‘L-like shape’ that is bent in the middle. The fifth upper dummy bonding pad 322E is indicated by a dotted line, and the fifth lower dummy bonding pad 322A is indicated by a solid line.

For example, a plurality of fifth lower dummy bonding pads 322A may be arranged on the top surface of the first semiconductor chip 100 along the second chip perimeter 210SA. The plurality of fifth lower dummy bonding pads 322A may be arranged, such that the second chip perimeter 210SA overlaps with the plurality of fifth lower dummy bonding pads 322A. The fifth upper dummy bonding pad 322E may be arranged along the second chip perimeter 210SA, but the fifth upper dummy bonding pad 322E may be arranged to not to deviate from the inner side of the second chip perimeter 210SA.

The shape of the fifth upper dummy bonding pad 322E in a plan view may substantially coincide with a portion of the shape of the fifth lower dummy bonding pad 322A in a plan view. Therefore, when the fifth upper dummy bonding pad 322E and the fifth lower dummy bonding pad 322A are directly bonded, a portion of the fifth lower dummy bonding pad 322A that does not match the fifth upper dummy bonding pad 322E may not contact the fifth upper dummy bonding pad 322E. Therefore, the encapsulation member 270 may contact the portion of the fifth lower dummy bonding pad 322A that does not match the fifth upper dummy bonding pad 322E.

In the semiconductor package 1B in which components are directly bonded by homogeneous bonding, the fifth dummy bonding pads 320E may be arranged at vertices (e.g., folded portions) of the second chip perimeter 210SA of the second semiconductor chip 200. The vertices of the second chip perimeter 210SA of the second semiconductor chip 200 may be vulnerable to peel-off occurring between the first semiconductor chip 100 and the second semiconductor chip 200. The bonding strength between the first semiconductor chip 100 and the second semiconductor chip 200 may be increased through the fifth dummy bonding pad 320E. Therefore, the reliability of the semiconductor package 1B according to embodiments may be improved.

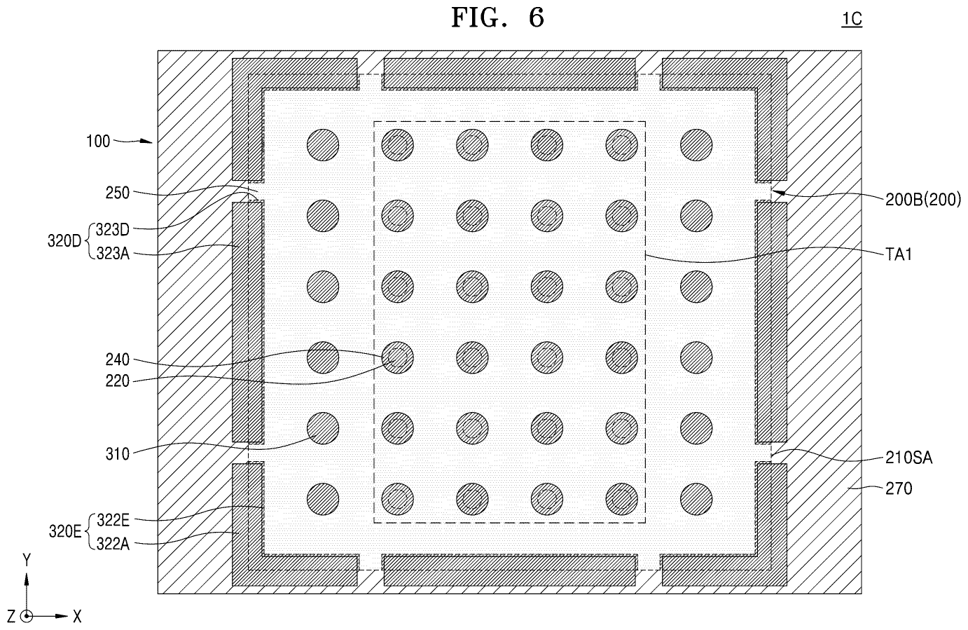

FIG. 6 is a cross-sectional view of a portion of a semiconductor package 1C identical to the portion B-B′ of FIG. 1. Descriptions not given below may be substantially identical to descriptions given above.

Referring to FIG. 6, the semiconductor package 1C may include the fourth dummy bonding pad 320D and the fifth dummy bonding pad 320E together. Detailed description of the fourth dummy bonding pad 320D is given above with reference to FIG. 4, and detailed specific description of the fifth dummy bonding pad 320E is given above with reference to FIG. 5.

FIG. 7 is a cross-sectional view of a portion of a semiconductor package 1D identical to the portion B-B′ of FIG. 1. FIG. 8 is a cross-sectional view of a portion of a semiconductor package 1E identical to the portion B-B′ of FIG. 1. FIG. 9 is a cross-sectional view of a portion of a semiconductor package 1F identical to the portion B-B′ of FIG. 1. Descriptions not given below may be substantially identical to descriptions given above.

Referring to FIG. 7, the semiconductor package 1D, according to embodiments, may further include the inner dummy bonding pad 310A between the first semiconductor chip 100 and the second semiconductor chip 200. Like the first dummy bonding pad 310, the inner dummy bonding pad 310A may be formed as an upper dummy bonding pad and a lower dummy bonding pad having the same shape are directly bonded to each other without being electrically connected to the first semiconductor chip 100 and/or the second semiconductor chip 200. The shape of the inner dummy bonding pad 310A in a plan view may be identical to that of the first dummy bonding pad 310, and, for example, the shape of the inner dummy bonding pad 310A in a plan view may be circular.

The inner dummy bonding pad 310A may be provided inside the first region TA1 instead of being adjacent to the second chip perimeter 210SA. In other words, the inner dummy bonding pad 310A may be provided adjacent to the first bonding pad 240. For example, as shown in FIG. 7, the inner dummy bonding pad 310A may be positioned adjacent to one or more first bonding pads 240.

Referring to FIG. 8, the semiconductor package 1E, according to embodiments, may further include the sixth dummy bonding pad 320F between the first semiconductor chip 100 and the second semiconductor chip 200. The sixth dummy bonding pad 320F may be formed by directly bonding a sixth upper dummy bonding pad 324B and a sixth lower dummy bonding pad 324A of the same shape without being electrically connected to the first semiconductor chip 100 and the second semiconductor chip 200. The shape of the sixth dummy bonding pad 320F in a plan view may be, for example, a ‘bar-like shape’ extending in one direction.

The sixth dummy bonding pad 320F may be provided inside the first region TA1 instead of being adjacent to the second chip perimeter 210SA. In other words, the sixth dummy bonding pad 320F may be provided adjacent to the first bonding pad 240. For example, as shown in FIG. 8, the sixth dummy bonding pad 320F may be positioned adjacent to a plurality of first bonding pads 240. In one or more examples, according to other embodiments, at least a portion of the sixth dummy bonding pad 320F may extend outside the first region TA1.

Referring to FIG. 9, the semiconductor package 1F, according to embodiments may further include the seventh dummy bonding pad 320G and the inner dummy bonding pad 310A between the first semiconductor chip 100 and the second semiconductor chip 200. The seventh dummy bonding pad 320G may be formed by directly bonding a seventh upper dummy bonding pad 325G and the sixth lower dummy bonding pad 324A of the same shape without being electrically connected to the first semiconductor chip 100 and the second semiconductor chip 200. The shape of the seventh dummy bonding pad 320G in a plan view may be, for example, an ‘L-shape’ with a portion bent. The inner dummy bonding pad 310A is described in detail in FIG. 7.

The seventh dummy bonding pad 320G is partially adjacent to the second chip perimeter 210SA. Furthermore, at least a portion of the seventh dummy bonding pad 320G may be provided inside the first region TA1. For example, a portion of the seventh dummy bonding pad 320G that does not include a bent portion may be positioned inside the first region TA1 as shown in FIG. 9. At least a portion of the seventh dummy bonding pad 320G may be provided adjacent to the first bonding pad 240. For example, as shown in FIG. 9, the seventh dummy bonding pad 320G may be positioned adjacent to the plurality of first bonding pads 240. In one or more examples, the seventh dummy bonding pad 320G may be provided adjacent to the inner dummy bonding pad 310A. In one or more examples, according to other embodiments, the entire portion of the seventh dummy bonding pad 320G may be provided within the first region TA1.

In each of semiconductor packages 1D, 1E, and 1F of FIGS. 7 to 9, a dummy bonding pad may be provided within the first region TA1 that is positioned between the first semiconductor chip 100 and the second semiconductor chip 200 while being spaced apart from a second chip perimeter 200SA of the second semiconductor chip 200, thereby ensuring bonding strength within the first semiconductor chip 100 and the second semiconductor chip 200. Therefore, the reliability of the semiconductor packages 1D, 1E, and 1F according to embodiments may be secured.

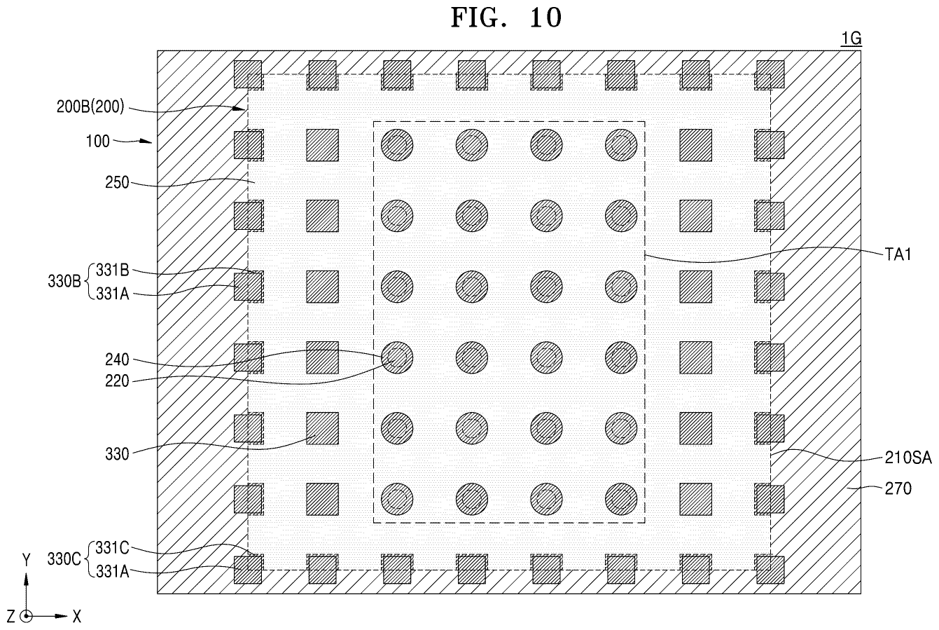

FIG. 10 is a cross-sectional view of a portion of a semiconductor package 1G identical to the portion B-B′ of FIG. 1. Descriptions not given below may be substantially identical to descriptions given above.

Referring to FIG. 10, the semiconductor package 1G according to embodiments may include an eighth dummy bonding pad 330, a ninth dummy bonding pad 330B, and a tenth dummy bonding pad 330C between the first semiconductor chip 100 and the second semiconductor chip 200.

The eighth dummy bonding pad 330, the ninth dummy bonding pad 330B, and the tenth dummy bonding pad 330C may not be electrically connected to the first semiconductor chip 100 and the second semiconductor chip 200. The eighth dummy bonding pad 330 is formed by directly bonding ab eighth upper dummy bonding pad and ab eighth lower dummy bonding pad, which have substantially the same shape in a plan view. The ninth dummy bonding pad 330B is formed by directly bonding a ninth upper dummy bonding pad 331B and a ninth lower dummy bonding pad 331A. The tenth dummy bonding pad 330C is formed by directly bonding a tenth upper dummy bonding pad 331C and the ninth lower dummy bonding pad 331A.

For example, as shown in FIG. 10, a plurality of ninth dummy bonding pads 330B and a plurality of tenth dummy bonding pads 330C may be arranged along the second chip perimeter 210SA. The tenth dummy bonding pads 330C may be provided at the vertices (bent portion) of the second chip perimeter 210SA.

The ninth dummy bonding pad 330B and the tenth dummy bonding pad 330C may have a rectangular shape.

For example, a plurality of ninth lower dummy bonding pads 331A may be arranged on the top surface of the first semiconductor chip 100 along the second chip perimeter 210SA. In one or more examples, the plurality of ninth lower dummy bonding pads 331A may be arranged, such that the plurality of ninth lower dummy bonding pads 331A overlap the second chip perimeter 210SA. Ninth upper dummy bonding pads 331B may be arranged along the second chip perimeter 210SA, but the ninth upper dummy bonding pads 331B may be arranged to not to deviate from the inner side of the second chip perimeter 210SA.

The shape of the ninth upper dummy bonding pad 331B in a plan view may substantially coincide with a portion of the shape of the ninth lower dummy bonding pad 331A in a plan view. For example, as shown in FIG. 10, the shape of the ninth lower dummy bonding pad 331A in a plan view may be rectangular, and the shape of the ninth upper dummy bonding pad 331B in a plan view may be a rectangle half the size of the rectangular shape of the ninth lower dummy bonding pad 331A.

when the ninth upper dummy bonding pad 331B and the ninth lower dummy bonding pad 331A are directly bonded, a portion of the ninth lower dummy bonding pad 331A that does not match the ninth upper dummy bonding pad 331B may not contact the ninth upper dummy bonding pad 331B. Therefore, the encapsulation member 270 may contact the portion of the ninth lower dummy bonding pad 331A that does not match the ninth upper dummy bonding pad 331B.

For example, the tenth upper dummy bonding pads 331C may be arranged along the second chip perimeter 210SA, but the tenth upper dummy bonding pad 331C may be arranged to not to deviate from the inner side of the second chip perimeter 210SA.

The shape of the tenth upper dummy bonding pad 331C in a plan view may substantially coincide with a portion of the shape of the ninth lower dummy bonding pad 331A in a plan view. For example, as shown in FIG. 10, the shape of the ninth lower dummy bonding pad 331A in a plan view may be rectangular, and the shape of the tenth upper dummy bonding pad 331C in a plan view may be a rectangle having the ¼ size of the rectangular shape of the ninth lower dummy bonding pad 331A. The encapsulation member 270 may contact the portion of the ninth lower dummy bonding pad 331A that does not match the tenth upper dummy bonding pad 331C.

In the semiconductor package 1G in which components are directly bonded by homogeneous bonding, the possibility of defects such as warpage of the semiconductor package 1G, peel-off occurring between the first semiconductor chip 100 and the second semiconductor chip 200, or short-circuit between the first semiconductor chip 100 and the second semiconductor chip 200 may be reduced. Therefore, since only homogeneous bonding is performed in direct bonding between semiconductor chips, the reliability of the semiconductor package 1G according to embodiments may be improved.

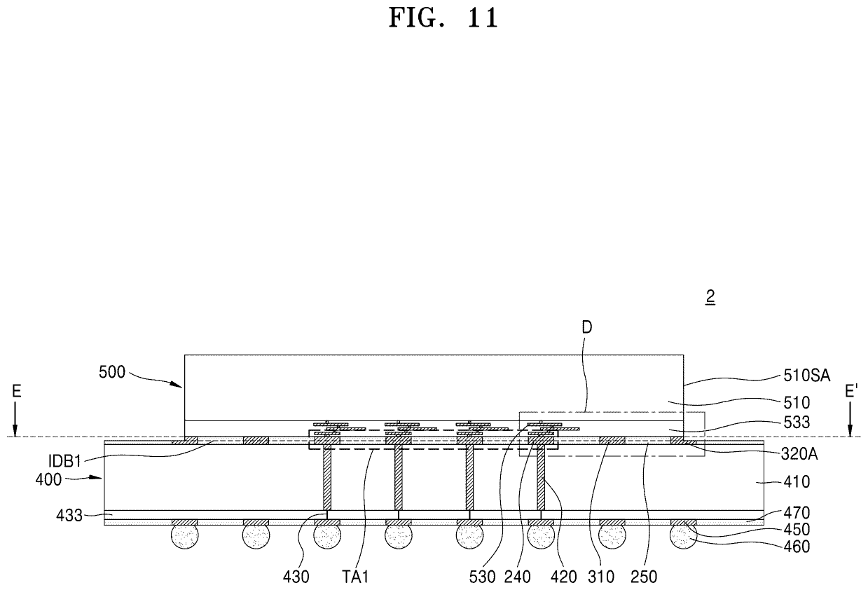

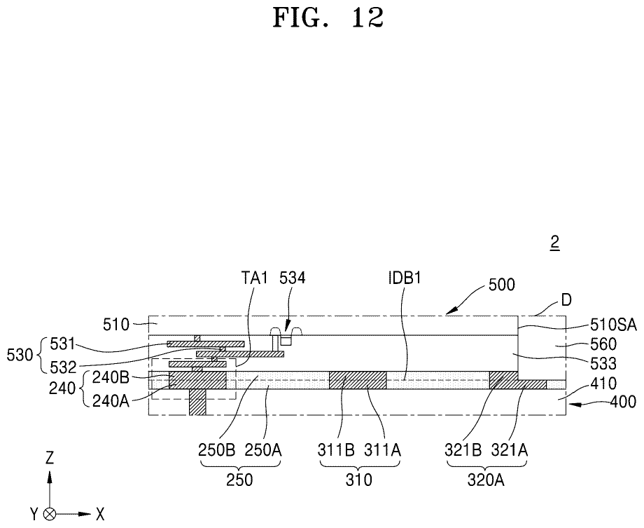

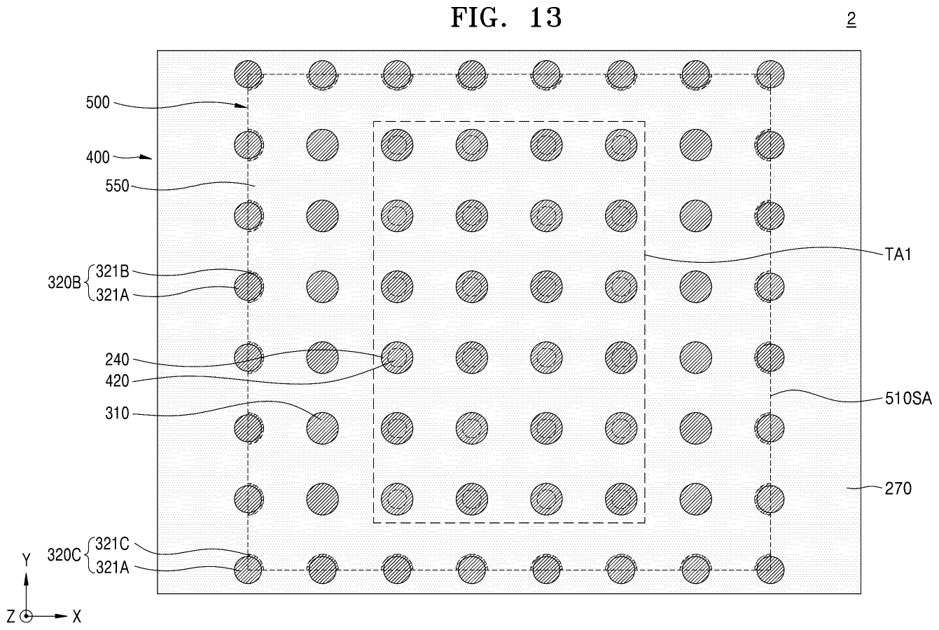

FIG. 11 is a cross-sectional view of a semiconductor package 2 according to embodiments. FIG. 12 is an enlarged cross-sectional view of a portion D of FIG. 11. FIG. 13 is a cross-sectional view taken along a portion E-E′ of FIG. 11, in a plan view. FIGS. 11 to 13 will be described based on the difference between the semiconductor package 2 and the semiconductor package 1 of FIGS. 1 to 3.

Referring to FIGS. 11 to 13, the semiconductor package 2 according to embodiments may include a first semiconductor chip 400 and a second semiconductor chip 500 provided on the first semiconductor chip 400. The shape of the first semiconductor chip 400 in a plan view may be larger than the shape of the second semiconductor chip 500 in a plan view.

The second semiconductor chip 500 may include a second semiconductor substrate 510, a second semiconductor device 534 provided on one surface of the second semiconductor substrate 510, a second front insulation layer 533 provided on the front (or bottom) surface of the second semiconductor substrate 510 and covering the second semiconductor device 534, a second wiring pattern 530 provided in the second front insulation layer 533, the first upper bonding pad 240B provided on the second front insulation layer 533, the first upper dummy bonding pad 311B provided on the second front insulation layer 533, the second upper dummy bonding pad 321B and the third upper dummy bonding pad 321C provided on the bottom surface of the second front insulation layer 533, and the first upper inter-chip insulation layer 250B provided on the bottom surface of the second front insulation layer 533. According to the design, the second semiconductor chip 500 may further include a second via electrode penetrating through at least a portion of the second semiconductor substrate 510.

The first semiconductor chip 400 may include a first semiconductor substrate 410, a first via electrode 420 vertically penetrating through at least a portion of the first semiconductor substrate 410, a first semiconductor device provided on one surface of the first semiconductor substrate 410, a first front insulation layer 433 disposed on the front (or bottom) surface of the first semiconductor substrate 410, a first wiring pattern 430 provided in the first front insulation layer 433, the first lower inter-chip insulation layer 250A provided on the top surface of the first semiconductor substrate 410, the first lower bonding pad 240A provided on the top surface of the first semiconductor substrate 410, the first lower dummy bonding pad 311A, the second lower dummy bonding pad 321A, the third upper dummy bonding pad 321C, a first front pad 450 disposed on the bottom surface of the first semiconductor chip 400, and a first lower passivation layer 470 surrounding a portion of the first front pad 450.

The first semiconductor chip 400 and the second semiconductor chip 500 may be chiplets constituting a multi-chip module (MCM). In this case, the number of the second semiconductor chips 500 stacked vertically or horizontally on the first semiconductor chip 400 may be one or more. The first semiconductor chip 400 may be a logic chip including, for example, a central processor (CPU), a graphics processor (GPU), a field programmable gate array (FPGA), an application processor (AP), a digital signal processor (DSP), an encryption processor, a microprocessor, a microcontroller, an analog-to-digital converter, an application-specific integrated circuit (ASIC), and the like, and the second semiconductor chip 500 may be a memory chip such as a DRAM, an SRAM, a PRAM, an MRAM, an FeRAM, or an RRAM.

Descriptions of the first dummy bonding pad 310, the second dummy bonding pad 320B, and the third dummy bonding pad 320C of FIGS. 11 to 13 are substantially identical to descriptions of the first dummy bonding pad 310, the second dummy bonding pad 320B, and the third dummy bonding pad 320C of FIGS. 1 to 3, except for the second via electrode 220 of FIGS. 1 to 3. For example, the boundary formed by side surfaces of the second semiconductor chip 500 may be referred to as a second chip perimeter 510SA. A portion of the second lower dummy bonding pad 321A may be located inside the second chip perimeter 510SA of the second semiconductor chip 500, and the remaining portion of the second lower dummy bonding pad 321A may be located outside the second chip perimeter 510SA.

The specification describes components as being “lower,” “upper,” etc. In one or more examples, these components may be alternatively disclosed as:

| Original Term | Revised Term |
|---|---|
| a first lower inter-chip insulation layer | a first inter-chip insulation layer |
| a first upper inter-chip insulation layer | a second inter-chip insulation |
| | layer |
| a first lower bonding pad | a first bonding pad |
| a first upper bonding pad | a second bonding pad |
| a first lower dummy bonding pad | a first dummy bonding pad |
| a first upper dummy bonding pad | a second dummy bonding pad |
| a second lower dummy bonding pad | a third dummy bonding pad |
| a second upper dummy bonding pad | a fourth dummy bonding pad |
| an inner lower dummy bonding pad | a fifth dummy bonding pad |
| an inner upper dummy bonding pad | a sixth dummy bonding pad |

While the present disclosure has been particularly shown and described with reference to embodiments thereof, it will be understood that various changes in form and details may be made therein without departing from the spirit and scope of the following claims.

What is claimed is:

1. A semiconductor package comprising:
a first semiconductor chip comprising a first semiconductor substrate and a first via electrode passing through at least a portion of the first semiconductor substrate;
a second semiconductor chip on the first semiconductor chip and comprising a second semiconductor substrate;
a first bonding pad structure between the first semiconductor chip and the second semiconductor chip;
a first dummy bonding pad structure between the first semiconductor chip and the second semiconductor chip; and
a first inter-chip insulation layer on a surface of the first semiconductor chip, and a second inter-chip insulation layer on a surface of the second semiconductor chip,
wherein the first bonding pad structure comprises: a first bonding pad on the surface of the first semiconductor chip, and a second bonding pad on the surface of the second semiconductor chip,
wherein the first dummy bonding pad structure comprises: a first dummy bonding pad on the surface of the first semiconductor chip, and a second dummy bonding pad on the surface of the second semiconductor chip,
wherein the second bonding pad and the first bonding pad are in contact with each other and are directly bonded to each other, and
wherein the second dummy bonding pad and the first dummy bonding pad are in contact with each other and are directly bonded to each other, and
at least a portion of the first inter-chip insulation layer and the second inter-chip insulation layer are in contact with each other and directly bonded to each other.

2. The semiconductor package of claim 1, wherein the second bonding pad and the second dummy bonding pad are not in contact with the first inter-chip insulation layer, and
the first bonding pad and the first dummy bonding pad are not in contact with the second inter-chip insulation layer.

3. The semiconductor package of claim 1, wherein the first bonding pad structure connects the first semiconductor chip and the second semiconductor chip to each other, and
the first dummy bonding pad structure is not connected to the first semiconductor chip and the second semiconductor chip.

4. The semiconductor package of claim 1, further comprising a second dummy bonding pad structure between the first semiconductor chip and the second semiconductor chip,
wherein the second dummy bonding pad comprises: a third dummy bonding pad provided on the surface of the first semiconductor chip, and a fourth dummy bonding pad provided on the surface of the second semiconductor chip, and
the fourth dummy bonding pad and the third dummy bonding pad are not connected to the first semiconductor chip and the second semiconductor chip, respectively.

5. The semiconductor package of claim 4, wherein a portion of the fourth dummy bonding pad protrudes from a second chip perimeter of the second semiconductor chip toward a perimeter of the first semiconductor chip.

6. The semiconductor package of claim 4, wherein one surface of the fourth dummy bonding pad is aligned in a direction with a second chip perimeter of the second semiconductor chip, wherein the direction is perpendicular to the surface of the second semiconductor chip.

7. The semiconductor package of claim 4, wherein the fourth dummy bonding pad is in contact with a portion of the third dummy bonding pad, and a remaining portion of the third dummy bonding pad does not contact the second inter-chip insulation layer.

8. The semiconductor package of claim 4, wherein the second dummy bonding pad structure has a bar shape, and the second dummy bonding pad extends along a second chip perimeter of the second semiconductor chip.

9. The semiconductor package of claim 8, wherein, a first length, which is a length of one side of the second dummy bonding pad structure, is greater than a second length, which is a length of another side of the second dummy bonding pad structure,
the first length is about 20 μm to about 1 mm, and
the second length is about 10 μm to about 200 μm.

10. The semiconductor package of claim 4, wherein the second dummy bonding pad structure has an L shape having a bent portion, and the second dummy bonding pad structure extends along a second chip perimeter of the second semiconductor chip.

11. The semiconductor package of claim 10, wherein the second dummy bonding pad structure is a plurality of second dummy bonding pad structures, and
the plurality of second dummy bonding pad structures are symmetrically arranged around a center of the second semiconductor chip.

12. The semiconductor package of claim 4, further comprising an encapsulation member on the first semiconductor chip,
wherein the encapsulation member surrounds the second semiconductor chip,
wherein a portion of the third dummy bonding pad is in contact with the encapsulation member, and a remaining portion of the third dummy bonding pad is in contact with the fourth dummy bonding pad.

13. The semiconductor package of claim 1, further comprising a third dummy bonding pad structure between the first semiconductor chip and the second semiconductor chip,
wherein the third dummy bonding pad structure comprises: an fifth dummy bonding pad on the surface of the first semiconductor chip, and an sixth dummy bonding pad on the surface of the second semiconductor chip,
the third dummy bonding pad structure is not connected to the first semiconductor chip and the second semiconductor chip, and
at least a portion of the third dummy bonding pad structure is within a first region that includes the first bonding pad structure between the first semiconductor chip and the second semiconductor chip.

14. The semiconductor package of claim 13, wherein the third dummy bonding pad structure has a bar shape, and the third dummy bonding pad structure extends along a second chip perimeter of the second semiconductor chip.

15. The semiconductor package of claim 1, wherein the first semiconductor chip comprises a buffer chip,
the second semiconductor chip comprises a memory chip,
at least one of the second semiconductor chip is stacked on the first semiconductor chip, and
the second semiconductor chip comprises a second via electrode passing through at least a portion of the second semiconductor substrate.

16. A semiconductor package comprising:
a first semiconductor chip comprising a first semiconductor substrate and a first via electrode passing through at least a portion of the first semiconductor substrate;
a second semiconductor chip on the first semiconductor chip and comprising a second semiconductor substrate and a second via electrode passing through at least a portion of the second semiconductor substrate;
a first bonding pad structure between the first semiconductor chip and the second semiconductor chip;
a first dummy bonding pad structure between the first semiconductor chip and the second semiconductor chip;
a second dummy bonding pad structure between the first semiconductor chip and the second semiconductor chip;
a first inter-chip insulation layer on a surface of the first semiconductor chip;
a second inter-chip insulation layer on a surface of the second semiconductor chip; and
an encapsulation member on the first semiconductor chip and surrounding the second semiconductor chip,
wherein the first bonding pad structure comprises: a first bonding pad on the surface of the first semiconductor chip, and a second bonding pad on the surface of the second semiconductor chip,
wherein the first dummy bonding pad structure comprises: a first dummy bonding pad on the surface of the first semiconductor chip, and a second dummy bonding pad on the surface of the second semiconductor chip,
wherein the second dummy bonding pad structure comprises: a third dummy bonding pad on the surface of the first semiconductor chip, and a fourth dummy bonding pad on the surface of the second semiconductor chip,
wherein the second bonding pad and the first bonding pad are in contact with each other and are directly bonded to each other,
wherein the second dummy bonding pad and the first dummy bonding pad are in contact with each other and are directly bonded to each other,
wherein at least a portion of the first inter-chip insulation layer and the second inter-chip insulation layer are in contact with each other and directly bonded to each other,
wherein a shape of the first semiconductor chip is larger than a shape of the second semiconductor chip, and
wherein one surface of the fourth dummy bonding pad is aligned in a direction with a second chip perimeter of the second semiconductor chip, wherein the direction is perpendicular to the surface of the second semiconductor chip.

17. The semiconductor package of claim 16, wherein the second bonding pad, the second dummy bonding pad, the fourth dummy bonding pad, and the first inter-chip insulation layer do not contact each other,
the first bonding pad, the first dummy bonding pad, the third dummy bonding pad, and the first inter-chip insulation layer do not contact each other, and
the fourth dummy bonding pad is in contact with a portion of the third dummy bonding pad, and a remaining portion of the third dummy bonding pad is in contact with the encapsulation member.

18. The semiconductor package of claim 16, wherein the first semiconductor chip comprises a buffer chip and the second semiconductor chip comprises a memory chip,
the first bonding pad structure connects the first semiconductor chip and the second semiconductor chip to each other, and
the first dummy bonding pad structure and the second dummy bonding pad structure are not connected to the first semiconductor chip and the second semiconductor chip, respectively.

19. The semiconductor package of claim 16, further comprising a third dummy bonding pad structure provided between the first semiconductor chip and the second semiconductor chip,
wherein the third dummy bonding pad comprises: a fifth dummy bonding pad on the surface of the first semiconductor chip, and a sixth dummy bonding pad on the surface of the second semiconductor chip,
wherein the third dummy bonding pad is not connected to the first semiconductor chip and the second semiconductor chip,
wherein at least a portion of the third dummy bonding pad structure is within a first region, and
wherein the first region is defined as a region between the first semiconductor chip and the second semiconductor chip, the first region comprising the first bonding pad structure, and not comprising the second dummy bonding pad structure.

20. A semiconductor package comprising:
a first semiconductor chip comprising a first semiconductor substrate and a first via electrode passing through at least a portion of the first semiconductor substrate;
a second semiconductor chip on the first semiconductor chip and comprising a second semiconductor substrate and a second via electrode passing through at least a portion of the second semiconductor substrate;
a first bonding pad structure between the first semiconductor chip and the second semiconductor chip;
a first dummy bonding pad structure between the first semiconductor chip and the second semiconductor chip;
a second dummy bonding pad structure between the first semiconductor chip and the second semiconductor chip;
a third dummy bonding pad structure between the first semiconductor chip and the second semiconductor chip;
a first inter-chip insulation layer on a surface of the first semiconductor chip, and a second inter-chip insulation layer on a surface of the second semiconductor chip; and
an encapsulation member on the first semiconductor chip and surrounding the second semiconductor chip,
wherein the first bonding pad structure comprises: a first bonding pad on the surface of the first semiconductor chip, and a second bonding pad on the surface of the second semiconductor chip,
wherein the first dummy bonding pad structure comprises: a first dummy bonding pad on the surface of the first semiconductor chip, and a second dummy bonding pad on the surface of the second semiconductor chip,
wherein the second dummy bonding pad structure comprises: a third dummy bonding pad on the surface of the first semiconductor chip, and a fourth dummy bonding pad on the surface of the second semiconductor chip,
wherein the third dummy bonding pad structure comprises: a fifth dummy bonding pad on the surface of the first semiconductor chip and a sixth dummy bonding pad on the surface of the second semiconductor chip,
wherein the second bonding pad and the first bonding pad are in contact with each other and are directly bonded to each other,
wherein the second dummy bonding pad and the first dummy bonding pad are in contact with each other and are directly bonded to each other,
wherein at least a portion of the first inter-chip insulation layer and the second inter-chip insulation layer are in contact with each other and directly bonded to each other,
wherein a shape of the first semiconductor chip is larger than a shape of the second semiconductor chip,
wherein one surface of the fourth dummy bonding pad is aligned in a direction with a second chip perimeter of the second semiconductor chip, wherein the direction is perpendicular to the surface of the second semiconductor chip,
wherein the second bonding pad, the second dummy bonding pad, the fourth dummy bonding pad, and the first inter-chip insulation layer do not contact each other,
wherein the first bonding pad, the first dummy bonding pad, the third dummy bonding pad, and the first inter-chip insulation layer do not contact each other,
wherein the fourth dummy bonding pad is in contact with a portion of the third dummy bonding pad, and a remaining portion of the third dummy bonding pad is in contact with the encapsulation member,
wherein the first semiconductor chip comprises a buffer chip and the second semiconductor chip comprises a memory chip,
wherein the first bonding pad structure connects the first semiconductor chip and the second semiconductor chip to each other,
wherein each of the first dummy bonding pad structure, the second dummy bonding pad structure, and the third dummy bonding pad structure is not connected to the first semiconductor chip and the second semiconductor chip,
wherein at least a portion of the third dummy bonding pad structure is within a first region, and
wherein the first region is defined as a region between the first semiconductor chip and the second semiconductor chip, the first region comprising the first bonding pad structure and not comprising the second dummy bonding pad structure.
